(19) United States
(12) Patent Application Publication
(10) Pub. No.: US 2002/0052119 A1
(43) Pub. Date: May 2, 2002

(54) IN-SITU FLOWING BPSG GAP FILL PROCESS USING HDP

(76) Inventor: PATRICK A. VAN CLEEMPUT, SUNNYVALE, CA (US)

Correspondence Address: SKJERVEN MORRILL MACPHERSON LLP, 25 METRO DRIVE, SUITE 700, SAN JOSE, CA, 95110, US

(21) Appl. No.: 09/281,839

(22) Filed: Mar. 31, 1999

(51) Int. Cl. H01L 21/302; H01L 21/461

(52) U.S. Cl. 438/710; 438/689

(57) ABSTRACT

A process for filling high aspect ratio gaps on substrates uses high density plasma deposition processes for depositing a BPSG layer. Deposition at conventional temperatures fills more of high aspect ratio gaps than prior methods. The BPSG layer is then reflowed to fill in any small voids remaining in the high aspect ratio gaps. In another embodiment, the deposition temperature is increased to allow the BPSG layer to reflow in-situ, thereby providing similar void-free high aspect ratio gap fill capabilities.

### BACKGROUND

1. Field of the Invention

The present invention relates generally to methods of forming dielectric layers during an integrated circuit fabrication process and, particularly, to a process for filling high aspect ratio gaps with BPSG layers.

2. Description of Related Art

In a typical semiconductor fabrication process, different materials are sequentially deposited over a silicon wafer or substrate to form a variety of layers having functions such as conductors, semiconductors, and insulators. Each subsequent layer is patterned, usually by photolithographic techniques, such that the sequence of layers forms a complex array of electronic circuitry. The resulting semiconductor device typically contains several conductive layers with different circuit elements. Dielectric layers are used to separate and insulate the conductive layers to prevent unwanted interactions between circuit elements. Furthermore, each layer should be approximately planar prior to deposition of the subsequent layer for proper fabrication of the semiconductor device. Doped glass is commonly used as the dielectric or insulating layer between conductive layers because the melting point of doped glass is typically much lower than regular glass or other dielectric materials. A lower melting temperature allows the doped glass to be planarized by reflowing with practical temperature ranges.

Reflowing refers to the glass being heated to a high enough temperature that surface tension effects cause the surface of the glass to smooth out. Thus, after deposition of the glass layer, the temperature is raised above the glass transition temperature to cause a thermal fusion flow. After a time period long enough to cause the glass to soften viscoelastically, the thermal fusion flow process planarizes the glass surface. Thus, after reflow, a subsequent layer (e.g., metal) is deposited on a substantially planar surface.

A typical doped glass layer deposited by chemical vapor deposition (CVD) is a phosphosilicate glass (PSG), i.e., glass doped by phosphorus (e.g., phosphine PH₃). PSG, however, has a high glass transition temperature, typically 1000° C. to 1100° C. to flow the PSG layer. These high temperatures can result in excessive diffusion of junctions, damage to circuit elements, and an unacceptable thermal budget. Therefore, the use of a PSG layer is limited to applications with high thermal budgets. The glass transition temperature can be reduced by doping the PSG with boron (e.g., diborane B₂H₆, F₃, or others) to form a borophosphosilicate glass (BPSG). The BPSG layer is typically deposited by CVD at atmospheric or sub-atmospheric pressure in a temperature range of 300° C. to 500° C. The BPSG is then reflowed at temperatures over 800° C., up to approximately 950° C. to planarize the glass surface. Deposition of the BPSG layer also fills gaps or trenches between circuit elements on the conductive layer to physically and electrically isolate the elements, thereby preventing unwanted interactions.

However, as semiconductor technology advances, circuit elements and interconnections on these conductive layers become increasingly more dense in response to needs for smaller and higher speed circuits. Consequently, the widths of the gaps between circuit elements decrease, thereby increasing gap aspect ratios, typically defined as the gap height divided by the gap width.

As shown in FIGS. 1A and 1B, conventional BPSG processes have trouble producing a planarized glass layer capable of filling high aspect ratio gaps, such as those present in advanced VLSI and ULSI MOS circuits. In FIG. 1A, stacked gate structures 10 or other circuit elements are formed on a substrate 20. A conformal layer 30 is deposited over the stacked gate structures 10, where layer 30 can be nitride or oxide spacers for protecting the edges of the stacked gate structures 10 during a later drain contact etch. BPSG is then deposited over the stacked gate structures by CVD in a reaction chamber at a temperature between 300° C. and 500° C. to form a BPSG layer 40. BPSG layer 40 fills lower aspect ratio gaps 50, but is unable to adequately fill higher aspect ratio gaps 60, leaving a void 70 in gap 60. The structure is then removed from the reaction chamber for heat treatment to reflow the BPSG layer 40. Reflow is typically performed at temperatures between 800° C. and 950° C. to planarize BPSG layer 40, as shown in FIG. 1B. However, even though filling part of void 70, reflow is not able to completely fill voids in high aspect ratio gaps. As a result, unwanted voids and discontinuities are left in the BPSG layer.

In addition, as mentioned above, glass reflow at these high temperatures can damage circuit elements, especially at micron and submicron levels where shallow junctions can break down due to thermal stress. Even at these high temperatures, reflow may not result in the desired level of planarization. The characteristics of BPSG reflow depend on various factors, such as film composition, film thickness, flow temperature, and flow time. By increasing the boron concentration, BPSG layer thickness, and/or reflow time, planarization can be increased while maintaining the same reflow temperature, or planarization can be maintained while reducing the reflow temperature. However, increasing the concentration of boron can result in crystalline instabilities and increased sensitivity and retention of moisture in the BPSG film. Increasing the thickness of the BPSG film increases the process times and fabrication costs, while increasing the reflow time increases the thermal budget for processing the wafer. Accordingly, it is difficult to reduce the glass transition temperature of BPSG below 800° C., as required for some heat-sensitive devices.

Therefore, conventional BPSG deposition and reflow processes may not be suitable for more advanced circuits with higher aspect ratio gaps and lower thermal budget requirements.

### SUMMARY

In accordance with the present invention, a high aspect ratio gap-fill process uses high density plasma (HDP) deposition processes to deposit a BPSG layer on high aspect ratio gaps. The deposited BPSG material is simultaneously sputter-etched to allow more of the gap to be filled during the deposition. In one embodiment, the weight concentration of boron in the BPSG film is between 3 and 7 wt %, and the deposition temperature is approximately between 600° C. and 800° C. By raising the deposition temperature to 100° C. to 150° C. above the glass transition temperature of the BPSG film, reflow can be performed in-situ to planarize the film and fill high aspect ratio gaps. In another embodiment, the weight concentration of boron in the BPSG film is between 3 and 7 wt %, and the deposition temperature is reduced to 300° C. to 500° C. The BPSG film is then reflowed at a temperature between 800° C. and 900° C. to planarize the film and to fill any remaining voids in high aspect ratio gaps. As a result, a BPSG layer can be used to fill high aspect ratio gaps without void formation and, if desired, planarized at low temperatures for structures with high aspect ratio gaps and/or low thermal budgets.

The present invention will be better understood in light of the following detailed description, taken together with the accompanying drawings.

### BRIEF DESCRIPTION OF THE DRAWINGS

FIGS. 1A and 1B are sequential views of a conventional BPSG deposition process;

FIGS. 2A-2E are sequential views of a BPSG HDP deposition process according to one embodiment of the present invention; and

FIGS. 3A-3D are sequential views of a BPSG HDP deposition process according to another embodiment of the present invention.

Use of the same reference numbers in different figures indicates similar or like elements.

### DETAILED DESCRIPTION

In accordance with the present invention, a borophosphosilicate glass (BPSG) layer is deposited during a high density plasma (HDP) process for high aspect ratio gap fill capabilities. In one embodiment, the deposition temperature is raised above the BPSG glass transition temperature, but below 800° C., so that deposition and reflow is performed in-situ at temperatures below 800° C. In another embodiment, the BPSG deposition occurs at conventional BPSG deposition temperatures. Higher aspect ratio gaps are more completely filled so that a subsequent conventional reflow is capable of filling any remaining voids in the high aspect ratio gaps.

The BPSG deposition using an HDP process employs chemical vapor deposition (CVD) with a gas mixture containing, but not limited to, oxygen (O₂), silane (SiH₄), a phosphorus source (e.g., phosphine PH₃), a boron source (e.g., diborane B₂H₆), and an etching component (an inert or Noble gas such as hydrogen (H), helium (He), neon (Ne), or argon (Ar)) to achieve simultaneous deposition and etching of the BPSG layer. The gas mixture is used to simultaneously deposit and etch the BPSG material, where the etching component is formed from O₂ and the inert gas, and where the deposition component is formed from SiH₄, O₂, the boron source, and the phosphorus source. In an HDP process, an RF bias is applied to a wafer substrate in a reaction chamber. Some of the gas molecules (particularly oxygen and the inert gas) in this gas mixture are ionized in the plasma and accelerate toward the wafer surface when the RF bias is applied to the substrate. Deposited material is thereby sputtered when the ions strike the surface. As a result, the BPSG material deposited on the wafer surface is simultaneously sputter-etched to help keep gaps open during the deposition process, thereby allowing higher gap aspect ratios to be filled. The BPSG layer can be reflowed for planarization after deposition at an increased temperature or in-situ at the deposition temperature.

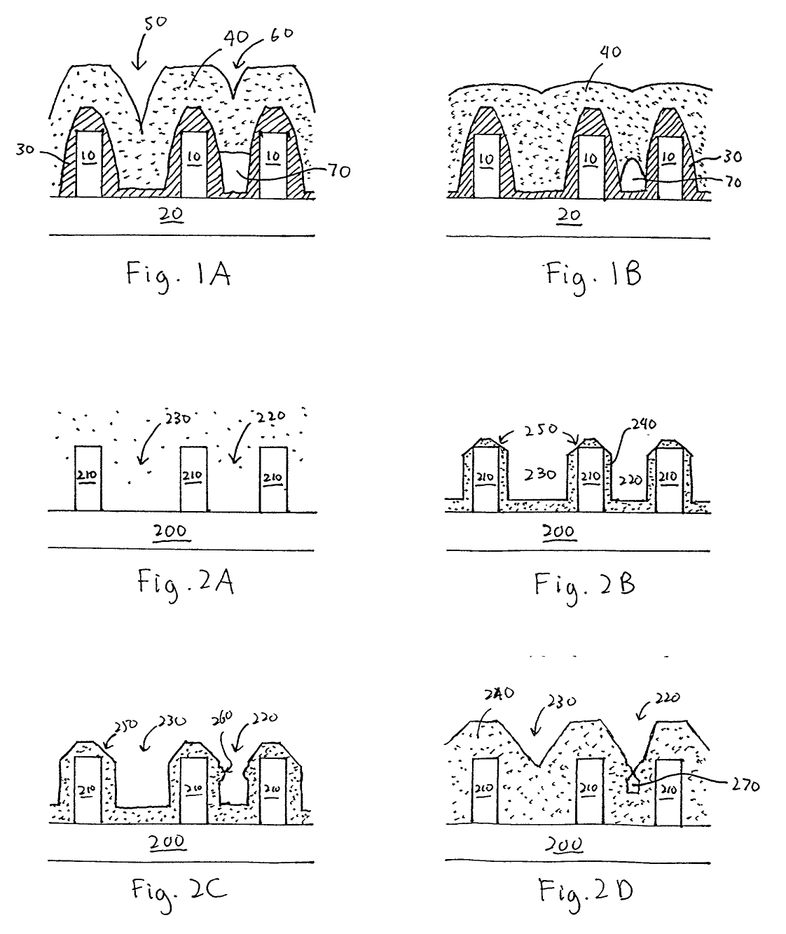

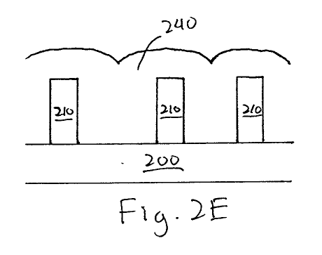

FIGS. 2A to 2E illustrate, in more detail, the simultaneous etch and deposition (etch/dep) process described above according to one embodiment of the invention. In FIG. 2A, circuit elements 210 are formed on a substrate or wafer 200, creating high aspect ratio gaps 220 (e.g., 3:1 or more) and lower ratio gaps 230 therebetween. Circuit elements 210 can be, for example, transistors, conductors, or interconnects. Gaps 220 and 230 are filled using HDP deposition, where sputtering is accomplished with the inert gas and O₂. The BPSG material, formed from SiH₄, O₂, the phosphorus source, and the boron source begins depositing on the surface of wafer 200 in a reaction chamber at a temperature between approximately 300° C. and 500° C. to start filling gaps 220 and 230 between circuit elements 210. (A conformal layer over the circuit elements, as shown in FIGS. 1A and 1B, is not shown here for simplicity.) As the BPSG material is being deposited, charged ions impinge on the BPSG layer 240, thereby simultaneously etching the BPSG layer. However, because the etch rate at about 45° is approximately three to four times the etch rate on the horizontal surface, 45° facets 250 form at the corners of elements 210 during the deposition process, as shown in FIG. 2B.

FIGS. 2C and 2D show the process continuing to fill gaps 220 and 230 with simultaneous etching and deposition of BPSG. With less efficient etching components (e.g., He is a less efficient etchant than Ar), facets 250 begin to move away from the corners of circuit elements 210 as more material deposits on the wafer surfaces, and cusps 260 begin to form on the sidewalls of high aspect ratio gap 220, but not on the sidewalls of lower aspect ratio gap 230. Cusp formation is due in part to some of the etched BPSG material being redeposited on opposing surfaces through line-of-sight redeposition, even though most of the etched BPSG material is emitted back into the plasma and pumped out of the reaction chamber. This redeposition increases as the distance between opposing surfaces decreases and/or as the etching component becomes less efficient. Therefore, as facets 250 move away from the corners of elements 210, the line-of-sight paths are shortened, resulting in increased sidewall redeposition. At a certain point in the process, cusps 260 will meet and prevent further deposition below the cusps. When this occurs, a small void 270 is created in gap 220 within BPSG layer 240, as shown in FIG. 2D. However, with lower aspect ratio gap 230, the gap is filled without a void as redeposition produces little or no cusps on the sidewalls. Thus, the process of the present invention fills a greater portion of high aspect ratio gaps than previous methods.

As an example, Table 1 below lists the gases used for BPSG HDP deposition and their respective gas flow ranges, with the actual gas flow amount dependent upon the requirements of the film and the wafer size.

TABLE 1

| Gas | Flow Rate (sccm) |
|---|---|
| B₂H₆ | 10-100 |
| PH₃ | 20-60 |
| SiH₄ | 80-200 |
| O₂ | 200-400 |
| Ar | 0-300 |

Low frequency (LF) power ranges from 1 kW to 10 kW, and high frequency (HF) power ranges from 0.5 kW to 10 kW, dependent upon the wafer size (e.g., 200 or 300 mm diameter) and the process being used. Typical in-film phosphorus concentrations are between 3 and 7 wt % and boron concentrations are between 4 and 6 wt %. This will ensure desired flow properties. In addition to gaseous sources, such as diborane B₂H₆ and phosphine PH₃, the boron and phosphorus for the BPSG layer can be provided from liquid or solid sources as well.

After BPSG deposition, BPSG layer 240 is reflowed using conventional processes, e.g., at a temperature between 800° C. and 900° C. for approximately 30 minutes to planarize the surface. Because only a small void 270 remains in high aspect ratio gap 220 after HDP deposition, reflow is capable of filling void 270, resulting in a void-free gap-fill for high aspect ratio gaps, as shown in FIG. 2E.

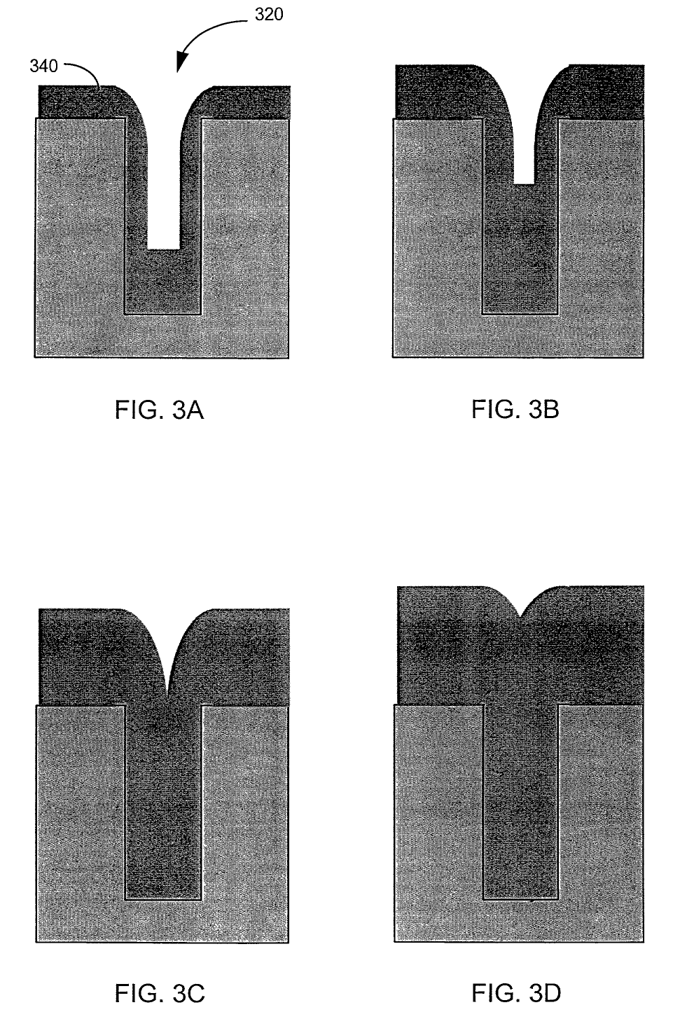

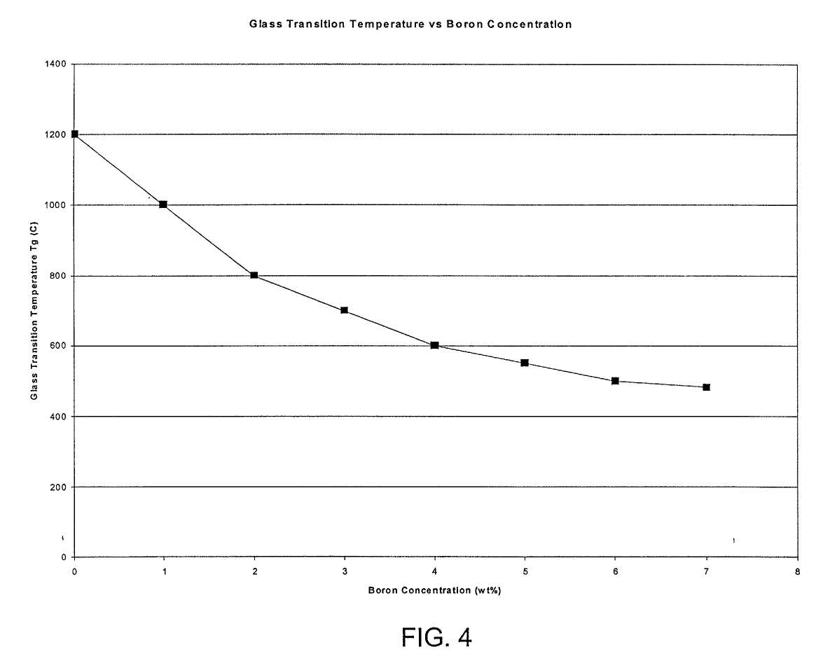

According to another aspect of the present invention, shown in FIGS. 3A to 3D, reflow is performed in-situ at the same temperature as BPSG deposition. In FIG. 3A, a BPSG layer 340 is deposited using the HDP deposition process described above to fill a high aspect ratio gap 320, but with a deposition temperature raised to approximately 600° C to 800° C. The concentration of boron in BPSG layer 340 is at about 5 wt %. At this concentration, the glass transition temperature of BPSG layer 340 is approximately 520° C. Thus, increasing the deposition temperature 100° C. to 150° C. above the glass transition temperature allows reflow to occur in-situ. The deposition temperature must be at least 100° C. above the glass transition temperature. FIGS. 3B to 3D show high aspect ratio gap 320 being filled and planarized in-situ. Contrary to the earlier described process in FIGS. 2A to 2E, the process described with respect to FIGS. 3A to 3D does not produce any voids at any time during the BPSG deposition. It should be noted that as the weight concentration of boron increases, the glass transition temperature decreases, as shown in FIG. 4. Thus, depending on the allowable thermal budget of the process, the concentration of boron can be adjusted accordingly. It should also be noted that the weight concentration of phosphorus has little or no effect on the thermal budget.

While particular embodiments of the present invention have been shown and described, it will be obvious to those skilled in the art that changes and modifications may be made without departing from this invention in its broader aspects. Therefore, the appended claims are to encompass within their scope all such changes and modifications as fall within the true spirit and scope of this invention.

I claim:

1. A process for filling gaps during integrated circuit production, comprising:
providing a gas mixture comprised of silicon-containing, oxygen-containing, phosphorus-containing, boron-containing, and inert components; and
depositing and reflowing a BPSG film over said gaps by using said gas mixture for simultaneous CVD and sputter etching in-situ at a temperature between approximately 600° C. and 800° C.

2. The process of claim 1, wherein said temperature is between approximately 600° C. and 700° C.

3. The process of claim 1, wherein said temperature is approximately 100° C. to 150° C. above the glass transition temperature of said BPSG film.

4. The process of claim 1, wherein said inert component is selected from the group consisting of helium, neon, hydrogen, and argon.

5. The process of claim 1, wherein said phosphorus-containing component is phosphine PH₃.

6. The process of claim 1, wherein said boron-containing component is diborane B₂H₆.

7. The process of claim 1, wherein said film contains between approximately 3 wt % and 7 wt % of boron.

8. A process for filling gaps during integrated circuit production, comprising:
providing a gas mixture comprised of silicon-containing, oxygen-containing, phosphorus-containing, boron-containing, and inert components;
depositing a BPSG film over said gaps by using said gas mixture for simultaneous CVD and sputter etching at a temperature between approximately 300° C. and 500° C.; and
reflowing said BPSG film at a temperature between approximately 800° C. and 900° C.

9. The process of claim 8, wherein said inert component is selected from the group consisting of helium, neon, hydrogen, and argon.

10. The process of claim 8, wherein said phosphorus-containing component is phosphine PH₃.

11. The process of claim 8, wherein said boron-containing component is selected from the group consisting of diborane B₂H₆ and BF₃.

12. The process of claim 8, wherein said film contains between approximately 3 wt % and 7 wt % of boron.

13. A process for filling gaps during integrated circuit production, comprising:
depositing and reflowing a BPSG film in-situ at a temperature between approximately 600° C. and 800° C. over said gaps by HDP deposition using a gas mixture comprised of silicon-containing, oxygen-containing, phosphorus-containing, boron-containing, and inert components.

14. The process of claim 13, wherein said temperature is between 600° C. and 700° C.

15. The process of claim 13, wherein said temperature is approximately 100° C. to 150° C. above the glass transition temperature of said BPSG film.
